(19) United States
(12) Patent Application Publication
(10) Pub. No.: US 2026/0040589 A1
(43) Pub. Date: Feb. 5, 2026

(54) ELECTRONIC COMPONENT

(71) Applicant: TDK Corporation, Tokyo (JP)

(72) Inventor: Aozora KAWASAKI, Tokyo (JP)

(73) Assignee: TDK Corporation, Tokyo (JP)

(21) Appl. No.: 19/283,279

(22) Filed: Jul. 29, 2025

(30) Foreign Application Priority Data
Aug. 2, 2024 (JP) 2024-127823

(51) Int. Cl. H10D 1/20; H01L 23/522; H10D 80/20

(52) U.S. Cl. CPC H10D 1/20; H01L 23/5225; H10D 80/211

(57) ABSTRACT

An electronic component 1 includes an element body, a first terminal electrode disposed on a main surface of the element body, a shield conductor disposed at a position closer to the main surface of the element body, a ninth conductor configured to connect the first terminal electrode and the shield conductor, and a first inductor and a second inductor disposed in the element body. The shield conductor is disposed at a position closer to the main surface in a second direction than a first inductor conductor or a second inductor conductor is. The shield conductor is positioned at least between the first inductor conductor and the second inductor conductor, and has a portion that does not overlap the first inductor conductor or the second inductor conductor, as viewed from the second direction.

### CROSS-REFERENCE TO RELATED APPLICATION

This application is based upon and claims the benefit of priority from Japanese Patent Application No. 2024-127823, filed on Aug. 2, 2024, the entire contents of which are incorporated herein by reference.

### TECHNICAL FIELD

The present disclosure relates to an electronic component.

### BACKGROUND

It is disclosed in Japanese Unexamined Patent Publication No. 2024-23011 that an electronic component includes a multilayer body including a stack of a plurality of dielectric layers, a first surface and a second surface; an input terminal, an output terminal, and a ground terminal disposed on the second surface of the multilayer body; a common electrode disposed on a first surface side of the multilayer body; a ground electrode coupled to the ground terminal; a first resonator and a second resonator disposed in a layer between the common electrode and the ground electrode; a shield electrode disposed closer to the first surface than the common electrode is and overlapping the entire common electrode as viewed in plan view in a stacking direction of the multilayer body; a first ground via coupling the shield electrode and the ground electrode via the common electrode; and a second ground via directly coupling the shield electrode and the ground electrode without passing the common electrode.

### SUMMARY

In an electronic component, leakage of magnetic flux or the like to the outside of the electronic component is suppressed by providing a shield conductor (shield electrode) on an element body (multilayer body). As a result, in the electronic component, deterioration of characteristics of the electronic component due to the relationship between the magnetic flux or the like leaking from the electronic component and the external shield or the like is suppressed. However, in a case where the shield conductor is disposed to cover inductors, a capacitance is formed by the inductors and the shield conductor. As a result, the characteristics of the electronic component may be deteriorated.

According to an aspect of the present disclosure, an object of the present disclosure is to provide an electronic component capable of suppressing deterioration of the characteristics even in a case where the shield conductor is provided in the element body.

(1) An electronic component according to an aspect of the present disclosure includes: an element body having a pair of end surfaces facing each other in a first direction, a main surface, and a mounting surface, the main surface and the mounting surface facing each other in a second direction; a ground terminal disposed on the mounting surface of the element body; a shield conductor disposed at a position closer to the main surface of the element body; a conductor configured to electrically connect the ground terminal and the shield conductor; and a first inductor and a second inductor disposed in the element body, each of the first inductor and the second inductor having an axial direction along the first direction, in which the first inductor includes a first conductor and a second conductor extending in the second direction, and a first connection conductor configured to connect an end portion of the first conductor closer to the main surface and an end portion of the second conductor closer to the main surface, the second inductor includes a third conductor and a fourth conductor extending in the second direction, and a second connection conductor configured to connect an end portion of the third conductor closer to the main surface and an end portion of the fourth conductor closer to the main surface, the first inductor and the second inductor are disposed adjacent to each other in the first direction, the shield conductor is disposed at a position closer to the main surface in the second direction than the first connection conductor or the second connection conductor is, and the shield conductor is at least positioned between the first connection conductor and the second connection conductor, and has a portion not overlapping the first connection conductor or the second connection conductor, as viewed from the second direction.

In the electronic component according to the aspect of the present disclosure, the shield conductor is positioned at least between the first connection conductor and the second connection conductor as viewed from the second direction. As a result, in the electronic component, leakage of magnetic flux or the like from between the first connection conductor (first inductor) and the second connection conductor (second inductor) to the outside of the electronic component can be suppressed by the shield conductor. Therefore, in the electronic component, it is possible to suppress deterioration of characteristics due to the leakage of magnetic flux or the like to the outside. In the electronic component, the shield conductor also has a portion that does not overlap the first connection conductor or the second connection conductor as viewed from the second direction. As described above, in the electronic component, the shield conductor does not entirely overlap the first inductor and the second inductor disposed in the element body. Therefore, in the electronic component, the capacitance formed between the shield conductor and the first inductor or second inductor can be reduced. Therefore, in the electronic component, it is possible to suppress deterioration of the characteristics due to capacitance formation.

(2) In the electronic component according to (1), the shield conductor may have a portion positioned between the first connection conductor and the second connection conductor and a portion overlapping the first connection conductor or the second connection conductor, as viewed from the second direction. With this configuration, since the shield conductor has a portion overlapping the first connection conductor or the second connection conductor, leakage of magnetic flux or the like from between the first connection conductor and the second connection conductor to the outside of the electronic component can be further suppressed by the shield conductor.

(3) In the electronic component according to (1) or (2), the electronic component may further include a third inductor disposed in the element body, with an axial direction of the third inductor along the first direction, in which the third inductor may include a fifth conductor and a sixth conductor extending in the second direction, and a third connection conductor configured to connect an end portion of the fifth conductor closer to the main surface and an end portion of the sixth conductor closer to the main surface, and the shield conductor may not overlap the third connection conductor as viewed from the second direction. As described above, in the electronic component, the shield conductor does not overlap the third inductor among the first inductor, the second inductor, and the third inductor disposed in the element body. That is, in the electronic component, the shield conductor overlaps with some, but not all, of the inductors. Therefore, in the electronic component, no capacitance is formed between the shield conductor and the third inductor. Therefore, in the electronic component, it is possible to suppress deterioration of the characteristics due to capacitance formation.

(4) In the electronic component according to any one of (1) to (3), an area of the shield conductor may be 1/2 or less of an area of the main surface. With this configuration, the shield conductor can be configured to overlap some, but not all, of the inductors disposed in the element body.

(5) In the electronic component according to any one of (1) to (4), a width of the shield conductor may be greater than a width of each of the first connection conductor and the second connection conductor. With this configuration, it is possible to suppress leakage of magnetic flux or the like from between the first connection conductor and the second connection conductor to the outside of the electronic component by securing the width of the shield conductor.

(6) In the electronic component according to any one of (1) to (5), the conductor may be disposed between the first connection conductor and the second connection conductor as viewed from the second direction.

(7) In the electronic component according to any one of (1) to (6), the conductor and an end portion, disposed closer to the mounting surface, of at least one of the first conductor, the second conductor, the third conductor, or the fourth conductor may be electrically connected via a connection conductor. With this configuration, the coupling between the first inductor and the second inductor can be adjusted.

(8) In the electronic component according to (7), the connection conductor connects two of end portions, disposed closer to the mounting surface, of the first conductor, the second conductor, the third conductor, and the fourth conductor at the same height position in the second direction, and lengths in the second direction of two conductors connected to the connection conductor, among the first conductor, the second conductor, the third conductor, and the fourth conductor, may be shorter than lengths in the second direction of two conductors not connected to the connection conductor. With this configuration, coupling between the first inductor and the second inductor can be adjusted while securing inductance of an inductor formed by a conductor.

(9) An electronic component according to an aspect of the present disclosure includes: an element body having a pair of end surfaces facing each other in a first direction, a main surface, and a mounting surface, the main surface and the mounting surface facing each other in a second direction; a ground terminal disposed on the mounting surface of the element body; a shield conductor disposed at a position closer to the main surface of the element body; a conductor configured to electrically connect the ground terminal and the shield conductor; and a first inductor, a second inductor, and a third inductor disposed in the element body, each of the first inductor, the second inductor, and the third inductor having an axial direction along the first direction, in which the first inductor includes a first conductor and a second conductor extending in the second direction, and a first connection conductor configured to connect an end portion of the first conductor closer to the main surface and an end portion of the second conductor closer to the main surface, the second inductor includes a third conductor and a fourth conductor extending in the second direction, and a second connection conductor configured to connect an end portion of the third conductor closer to the main surface and an end portion of the fourth conductor closer to the main surface, the third inductor includes a fifth conductor and a sixth conductor extending in the second direction, and a third connection conductor configured to connect an end portion of the fifth conductor closer to the main surface and an end portion of the sixth conductor closer to the main surface, the first inductor and the second inductor are disposed adjacent to each other in the first direction, the shield conductor is disposed at a position closer to the main surface in the second direction than the first connection conductor, the second connection conductor, or the third connection conductor is, and the shield conductor is at least positioned between the first connection conductor and the second connection conductor, and does not overlap the third connection conductor, as viewed from the second direction.

In the electronic component according to the aspect of the present disclosure, the shield conductor is positioned at least between the first connection conductor and the second connection conductor as viewed from the second direction. As a result, in the electronic component, leakage of magnetic flux or the like from between the first connection conductor (first inductor) and the second connection conductor (second inductor) to the outside of the electronic component can be suppressed by the shield conductor. Therefore, in the electronic component, it is possible to suppress deterioration of characteristics due to the leakage of magnetic flux or the like to the outside. In the electronic component, the shield conductor does not overlap the third connection conductor (third inductor) as viewed from the second direction. As described above, in the electronic component, the shield conductor does not overlap at least the third inductor among the first inductor, the second inductor, and the third inductor disposed in the element body. That is, in the electronic component, the shield conductor overlaps with some, but not all, of the inductors. Therefore, in the electronic component, no capacitance is formed between the shield conductor and the third inductor. Therefore, in the electronic component, it is possible to suppress deterioration of the characteristics due to capacitance formation.

According to the aspect of the present disclosure, even in a case where the shield conductor is provided in the element body, deterioration of characteristics can be suppressed.

### BRIEF DESCRIPTION OF THE DRAWINGS

FIG. 1 is a transparent perspective view of an electronic component according to an embodiment;

FIG. 2 is a side view of the electronic component illustrated in FIG. 1;

FIG. 3 is an end view of the electronic component illustrated in FIG. 1;

FIG. 4 is an end view of the electronic component illustrated in FIG. 1;

FIG. 5 is an exploded perspective view of the electronic component illustrated in FIG. 1;

FIG. 6 is a view of the electronic component as viewed from one main surface side; and

FIG. 7 is an equivalent circuit diagram of the electronic component.

### DETAILED DESCRIPTION

Hereinbelow, preferred embodiments of the present invention will be described in detail with reference to the accompanying drawings. Note that, in the description of the drawings, the same or corresponding elements are denoted by the same reference numerals, and redundant descriptions thereof will be omitted.

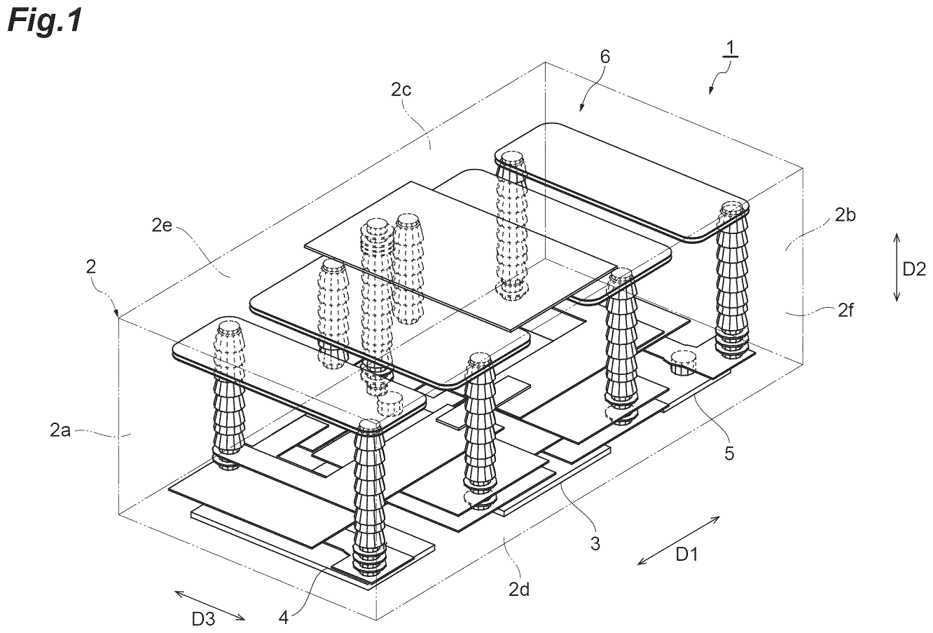

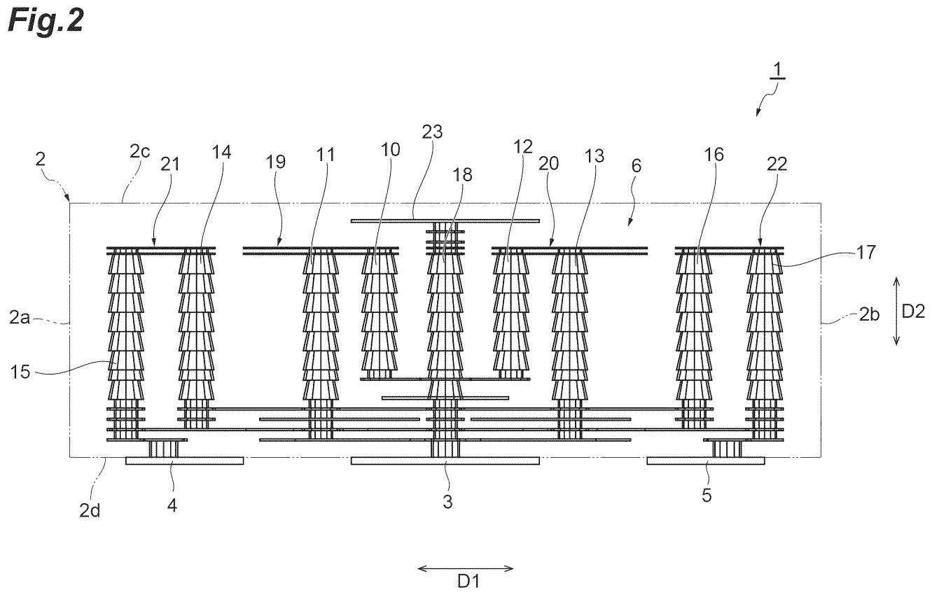

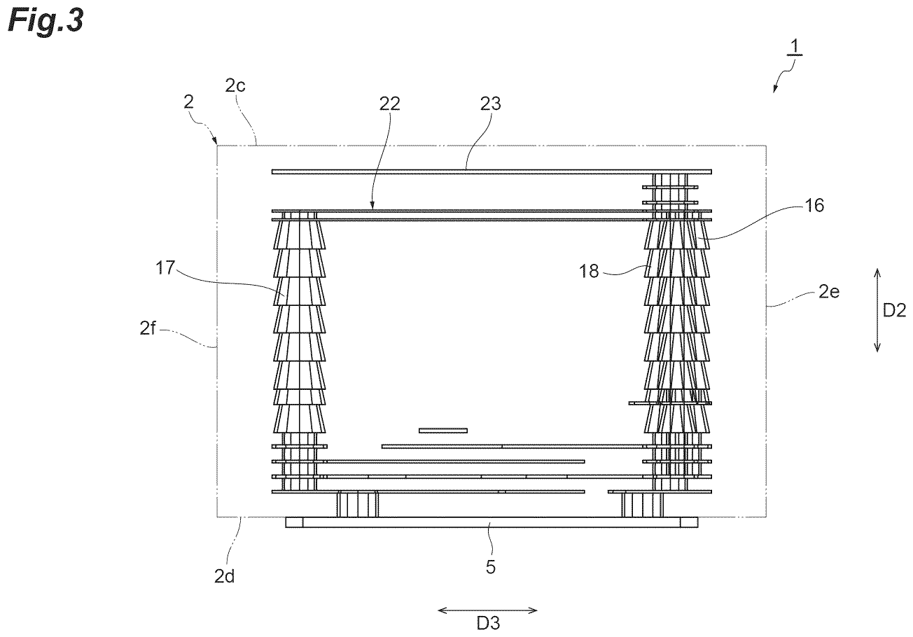

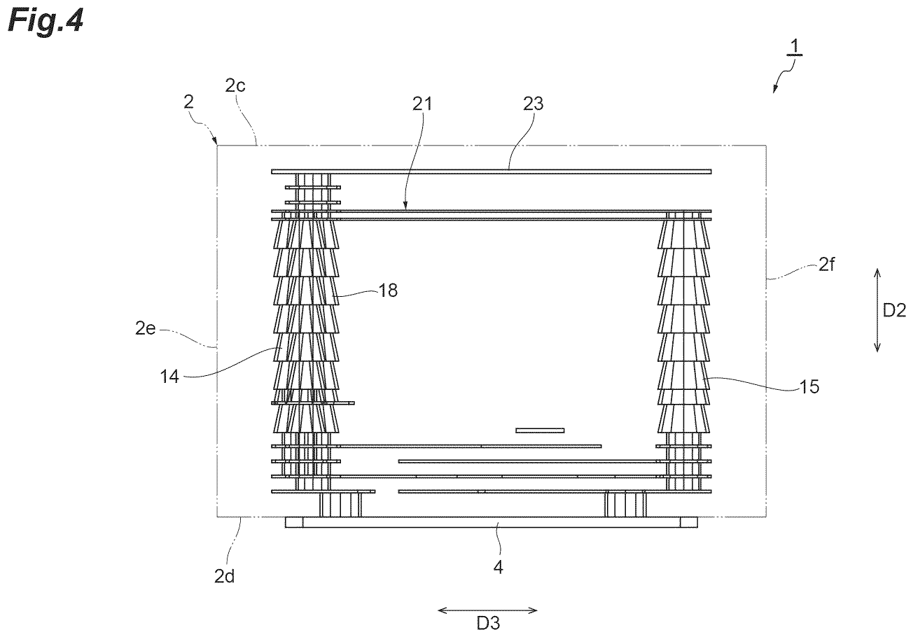

An electronic component according to an embodiment will be described with reference to FIGS. 1, 2, 3, and 4. FIG. 1 is a transparent perspective view of the electronic component according to the embodiment. FIG. 2 is a side view of the electronic component illustrated in FIG. 1. FIGS. 3 and 4 are end views of the electronic component illustrated in FIG. 1. As illustrated in FIGS. 1 to 4, an electronic component 1 includes an element body 2, a first terminal electrode 3, a second terminal electrode 4, a third terminal electrode 5, and a resonator 6. In FIGS. 1 to 4, the element body 2 is indicated by a dashed double-dotted line.

The element body 2 has a rectangular parallelepiped shape. The rectangular parallelepiped shape includes a rectangular parallelepiped shape in which corner portions and ridge line portions are chamfered, and a rectangular parallelepiped shape in which corner portions and ridge line portions are rounded. The element body 2 has, as outer surfaces, a pair of end surfaces 2a and 2b, a pair of main surfaces 2c and 2d, and a pair of side surfaces 2e and 2f. The end surfaces 2a and 2b face each other. The main surfaces 2c and 2d face each other. The side surfaces 2e and 2f face each other. In the following, the facing direction of the end surfaces 2a and 2b is defined as a first direction D1, the facing direction of the main surfaces 2c and 2d is defined as a second direction D2, and the facing direction of the side surfaces 2e and 2f is defined as a third direction D3. The first direction D1, the second direction D2, and the third direction D3 are substantially orthogonal to each other.

The end surfaces 2a and 2b extend in the second direction D2 so as to connect the main surfaces 2c and 2d. The end surfaces 2a and 2b also extend in the third direction D3 so as to connect the side surfaces 2e and 2f. The main surfaces 2c and 2d extend in the first direction D1 to connect the end surfaces 2a and 2b. The main surfaces 2c and 2d also extend in the third direction D3 so as to connect the side surfaces 2e and 2f. The side surfaces 2e and 2f extend in the first direction D1 to connect the end surfaces 2a and 2b. The side surfaces 2e and 2f also extend in the second direction D2 so as to connect the main surfaces 2c and 2d.

The main surface 2d is a mounting surface; for example, when the electronic component 1 is mounted on another electronic device (for example, a circuit base material or a multilayer electronic component) (not illustrated), the main surface 2d faces the other electronic device. The end surfaces 2a and 2b are surfaces continuing from the mounting surface (that is, the main surface 2d).

A length of the element body 2 in the first direction D1 is longer than a length of the element body 2 in the second direction D2 and a length of the element body 2 in the third direction D3. The length of the element body 2 in the second direction D2 is shorter than the length of the element body 2 in the third direction D3. That is, in the present embodiment, each of the end surfaces 2a and 2b, the main surfaces 2c and 2d, and the side surfaces 2e and 2f has a rectangular shape. The length of the element body 2 in the second direction D2 may be equal to the length of the element body 2 in the third direction D3, or may be longer than the length of the element body 2 in the third direction D3.

In the present embodiment, “equal” may mean not only “equal” but also a value including a minute difference, a manufacturing error, or the like in a preset range. For example, when a plurality of values is included within a range of ±5% of an average value of the plurality of values, the plurality of values is defined to be equivalent.

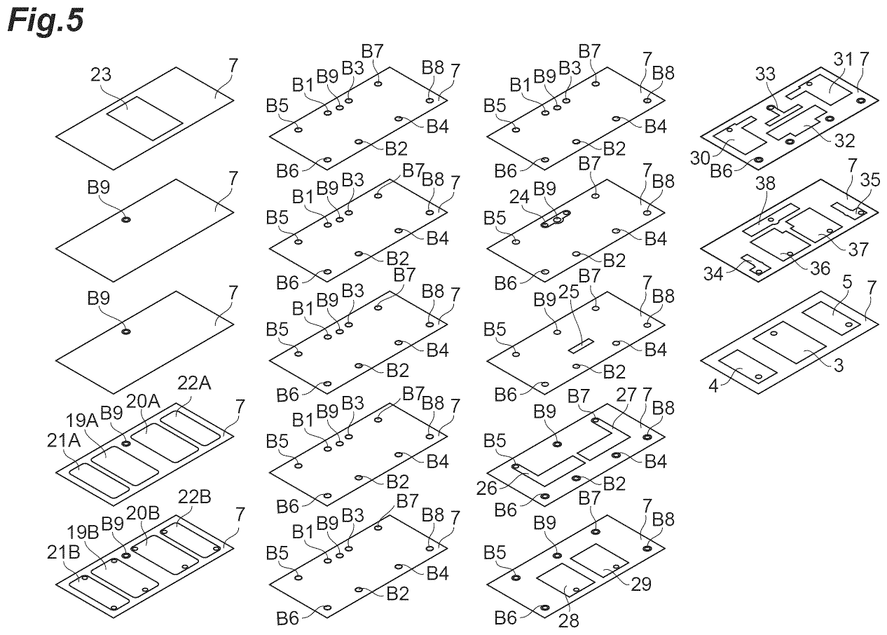

The element body 2 is formed by stacking a plurality of element body layers (insulator layers) 7 (see FIG. 5) in the second direction D2. That is, the stacking direction of the element body 2 is the second direction D2. In the actual element body 2, the plurality of element body layers 7 may be integrated to such an extent that boundaries between the layers cannot be visually recognized, or may be integrated such that boundaries between the layers can be visually recognized.

The element body layer 7 is formed by using, for example, a sintered body of a ceramic green sheet containing a dielectric material. The dielectric material includes, for example, at least one selected from a BaTiO₃-based material, a Ba(Ti,Zr)O₃-based material, a (Ba,Ca)TiO₃-based material, a glass material, and an alumina material.

Each of the first terminal electrode 3, the second terminal electrode 4, and the third terminal electrode 5 is provided on the element body 2. Each of the first terminal electrode 3, the second terminal electrode 4, and the third terminal electrode 5 is disposed on the main surface 2d of the element body 2. Each of the first terminal electrode 3, the second terminal electrode 4, and the third terminal electrode 5 has a rectangular shape (rectangle). Each of the first terminal electrode 3, the second terminal electrode 4, and the third terminal electrode 5 is disposed such that each side is along the first direction D1 or the third direction D3. In the present embodiment, a length of the first terminal electrode 3 in the first direction D1 is longer than lengths of the second terminal electrode 4 and the third terminal electrode 5 in the first direction D1.

As illustrated in FIG. 2, the first terminal electrode 3, the second terminal electrode 4, and the third terminal electrode 5 are disposed apart from each other in the first direction D1. The first terminal electrode 3 is disposed at a central position in the first direction D1 on the main surface 2d. The second terminal electrode 4 is disposed at a position closer to the end surface 2a on the main surface 2d. The third terminal electrode 5 is disposed at a position closer to the end surface 2b on the main surface 2d. The first terminal electrode 3 is disposed between the second terminal electrode 4 and the third terminal electrode 5 in the first direction D1.

Each of the first terminal electrode 3, the second terminal electrode 4, and the third terminal electrode 5 protrudes from the main surface 2d. That is, in the present embodiment, respective surfaces of the first terminal electrode 3, the second terminal electrode 4, and the third terminal electrode 5 are not flush with the main surface 2d. Each of the first terminal electrode 3, the second terminal electrode 4, and the third terminal electrode 5 contains a conductive material (for example, Cu).

A plating layer (not illustrated) containing, for example, Ni, Sn, Au, or the like may be provided on each of the first terminal electrode 3, the second terminal electrode 4, and the third terminal electrode 5 by electrolytic plating or non-electrolytic plating. The plating layer may have a Ni-plated film covering the first terminal electrode 3, the second terminal electrode 4, and the third terminal electrode 5, and an Au-plated film containing Au and covering the Ni-plated film.

FIG. 5 is an exploded perspective view of the electronic component 1 illustrated in FIG. 1. As illustrated in FIGS. 1 to 5, the resonator 6 includes a first conductor 10, a second conductor 11, a third conductor 12, a fourth conductor 13, a fifth conductor 14, a sixth conductor 15, a seventh conductor 16, an eighth conductor 17, a ninth conductor (conductor) 18, a first inductor conductor (first connection conductor) 19, a second inductor conductor (second connection conductor) 20, a third inductor conductor (third connection conductor) 21, a fourth inductor conductor (fourth connection conductor) 22, a shield conductor 23, a connection conductor 24, a capacitor conductor 25, a capacitor conductor 26, a capacitor conductor 27, a capacitor conductor 28, a capacitor conductor 29, a capacitor conductor 30, a capacitor conductor 31, a capacitor conductor 32, a capacitor conductor 33, a capacitor conductor 34, a capacitor conductor 35, a capacitor conductor 36, and a capacitor conductor 37.

The first conductor 10 extends along the second direction D2. The first conductor 10 can include a plurality of via conductors B1. The first conductor 10 is disposed at a position closer to the center in the first direction D1 (the position closer to the end surface 2a than the center is) and at a position closer to the side surface 2e. The first conductor 10 electrically connects the first inductor conductor 19 and the connection conductor 24.

The second conductor 11 extends along the second direction D2. The second conductor 11 can include a plurality of via conductors B2. A length of the second conductor 11 in the second direction D2 is longer than that of the first conductor 10. In other words, the length of the first conductor 10 in the second direction D2 is shorter than that of the second conductor 11. The second conductor 11 is disposed at a position closer to the center in the first direction D1 (the position closer to the end surface 2a than the center is) and at a position closer to the side surface 2f. The second conductor 11 is disposed at a position that does not face the first conductor 10 in the third direction D3. The second conductor 11 is disposed at a position closer to the end surface 2a in the first direction D1 than the first conductor 10 is. The second conductor 11 electrically connects the first inductor conductor 19 and the capacitor conductor 28.

The third conductor 12 extends along the second direction D2. The third conductor 12 can include a plurality of via conductors B3. The third conductor 12 is disposed at a position closer to the center in the first direction D1 (the position closer to the end surface 2b than the center is) and at a position closer to the side surface 2e. The third conductor 12 electrically connects the second inductor conductor 20 and the connection conductor 24.

The fourth conductor 13 extends along the second direction D2. The fourth conductor 13 can include a plurality of via conductors B4. A length of the fourth conductor 13 in the second direction D2 is longer than that of the third conductor 12. In other words, the length of the third conductor 12 in the second direction D2 is shorter than that of the fourth conductor 13. The fourth conductor 13 is disposed at a position closer to the center in the first direction D1 (the position closer to the end surface 2b than the center is) and at a position closer to the side surface 2f. The fourth conductor 13 is disposed at a position that does not face the third conductor 12 in the third direction D3. The fourth conductor 13 is disposed at a position closer to the end surface 2b in the first direction D1 than the third conductor 12 is. The fourth conductor 13 electrically connects the second inductor conductor 20 and the capacitor conductor 29.

The fifth conductor 14 extends along the second direction D2. The fifth conductor 14 can include a plurality of via conductors B5. The fifth conductor 14 is disposed at a position closer to the end surface 2a and closer to the side surface 2e. The fifth conductor 14 electrically connects the third inductor conductor 21 and the capacitor conductor 26.

The sixth conductor 15 extends along the second direction D2. The sixth conductor 15 can include a plurality of via conductors B6. The sixth conductor 15 is disposed at a position closer to the end surface 2a and closer to the side surface 2f. The sixth conductor 15 is disposed at a position that does not face the fifth conductor 14 in the third direction D3. The sixth conductor 15 is disposed at a position closer to the end surface 2a in the first direction D1 than the fifth conductor 14 is. The sixth conductor 15 electrically connects the third inductor conductor 21 and the capacitor conductor 34.

The seventh conductor 16 extends along the second direction D2. The seventh conductor 16 can include a plurality of via conductors B7. The seventh conductor 16 is disposed at a position closer to the end surface 2b and closer to the side surface 2e. The seventh conductor 16 electrically connects the fourth inductor conductor 22 and the capacitor conductor 27.

The eighth conductor 17 extends along the second direction D2. The eighth conductor 17 can include a plurality of via conductors B8. The eighth conductor 17 is disposed at a position closer to the end surface 2b and closer to the side surface 2f. The eighth conductor 17 is disposed at a position that does not face the seventh conductor 16 in the third direction D3. The eighth conductor 17 is disposed at a position closer to the end surface 2b in the first direction D1 than the seventh conductor 16 is. The eighth conductor 17 electrically connects the fourth inductor conductor 22 and the capacitor conductor 35.

In the present embodiment, the first conductor 10, the third conductor 12, the fifth conductor 14, and the seventh conductor 16 are disposed on the same straight line in the first direction D1. The second conductor 11, the fourth conductor 13, the sixth conductor 15, and the eighth conductor 17 are disposed on the same straight line in the first direction D1.

The ninth conductor 18 extends along the second direction D2. The ninth conductor 18 can include a plurality of via conductors B9. The ninth conductor 18 is disposed at the center in the first direction D1. The ninth conductor 18 is disposed between the first conductor 10 and the third conductor 12 as viewed from the third direction D3.

The first inductor conductor 19 electrically connects the first conductor 10 and the second conductor 11. The first inductor conductor 19 extends along the third direction D3. The first inductor conductor 19 has a substantially rectangular shape as viewed from the second direction D2. The first inductor conductor 19 connects an end portion on one side (main surface 2c side) of the first conductor 10 and an end portion on one side of the second conductor 11. The end portion of the first conductor 10 is connected to the end portion of the first inductor conductor 19 at a position closer to the side surface 2e and closer to the end surface 2b. The end portion of the second conductor 11 is connected to the end portion of the first inductor conductor 19 closer to the side surface 2f at the central position in the first direction D1.

The first inductor conductor 19 includes an inductor pattern 19A and an inductor pattern 19B. The inductor pattern 19A and the inductor pattern 19B have the same shape. The inductor pattern 19A and the inductor pattern 19B are disposed to face each other in the second direction D2.

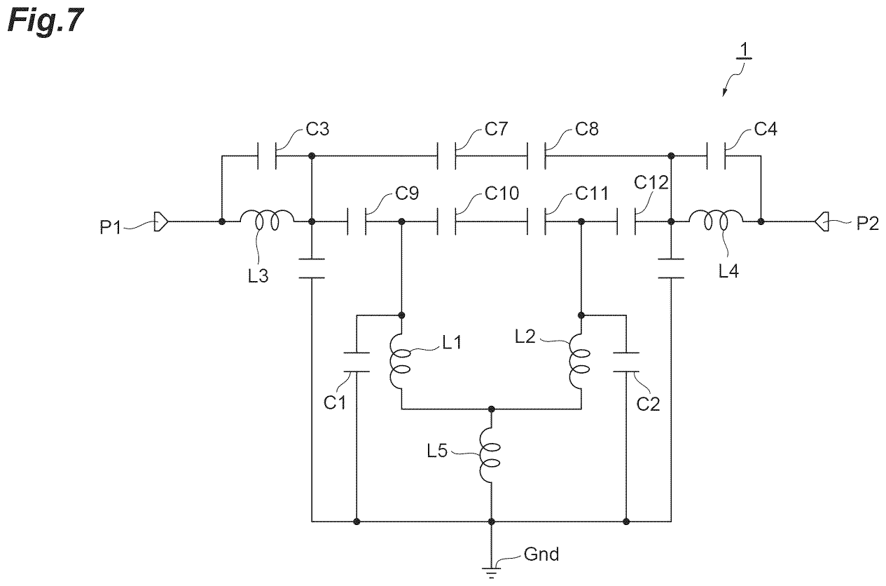

The first conductor 10, the second conductor 11, and the first inductor conductor 19 constitute a first inductor L1 (see FIG. 7). The axial direction of the first inductor L1 including the first conductor 10, the second conductor 11, and the first inductor conductor 19 is along the first direction D1.

The second inductor conductor 20 electrically connects the third conductor 12 and the fourth conductor 13. The second inductor conductor 20 extends along the third direction D3. The second inductor conductor 20 has a substantially rectangular shape as viewed from the second direction D2. The second inductor conductor 20 connects an end portion on one side of the third conductor 12 and an end portion on one side of the fourth conductor 13. The end portion of the third conductor 12 is connected to the end portion of the second inductor conductor 20 at a position closer to the side surface 2e and closer to the end surface 2a. The end portion of the fourth conductor 13 is connected to the end portion of the second inductor conductor 20 closer to the side surface 2f at the central position in the first direction D1.

The second inductor conductor 20 includes an inductor pattern 20A and an inductor pattern 20B. The inductor pattern 20A and the inductor pattern 20B have the same shape. The inductor pattern 20A and the inductor pattern 20B are disposed to face each other in the second direction D2.

The third conductor 12, the fourth conductor 13, and the second inductor conductor 20 constitute a second inductor L2 (see FIG. 7). The axial direction of the second inductor L2 including the third conductor 12, the fourth conductor 13, and the second inductor conductor 20 is along the first direction D1.

The third inductor conductor 21 electrically connects the fifth conductor 14 and the sixth conductor 15. The third inductor conductor 21 extends along the third direction D3. The third inductor conductor 21 has a substantially rectangular shape as viewed from the second direction D2. The third inductor conductor 21 connects an end portion on one side of the fifth conductor 14 and an end portion on one side of the sixth conductor 15. The end portion of the fifth conductor 14 is connected to the end portion of the third inductor conductor 21 at a position closer to the side surface 2e and closer to the end surface 2b. The end portion of the sixth conductor 15 is connected to the end portion of the third inductor conductor 21 at a position closer to the side surface 2f and closer to the end surface 2a. The end portion of the fifth conductor 14 and the end portion of the sixth conductor 15 are positioned on the third inductor conductor 21 along a diagonal of the third inductor conductor 21.

The third inductor conductor 21 includes an inductor pattern 21A and an inductor pattern 21B. The inductor pattern 21A and the inductor pattern 21B have the same shape. The inductor pattern 21A and the inductor pattern 21B are disposed to face each other in the second direction D2.

The fifth conductor 14, the sixth conductor 15, and the third inductor conductor 21 constitute a third inductor L3 (see FIG. 7). The axial direction of the third inductor L3 including the fifth conductor 14, the sixth conductor 15, and the third inductor conductor 21 is along the first direction D1.

The fourth inductor conductor 22 electrically connects the seventh conductor 16 and the eighth conductor 17. The fourth inductor conductor 22 extends along the third direction D3. The fourth inductor conductor 22 has a substantially rectangular shape as viewed from the second direction D2. The fourth inductor conductor 22 connects an end portion on one side of the seventh conductor 16 and an end portion on one side of the eighth conductor 17. The end portion of the seventh conductor 16 is connected to the end portion of the fourth inductor conductor 22 at a position closer to the side surface 2e and closer to the end surface 2a. The end portion of the eighth conductor 17 is connected to the end portion of the fourth inductor conductor 22 at a position closer to the side surface 2f and closer to the end surface 2b. The end portion of the seventh conductor 16 and the end portion of the eighth conductor 17 are positioned on the fourth inductor conductor 22 along a diagonal of the fourth inductor conductor 22.

The fourth inductor conductor 22 includes an inductor pattern 22A and an inductor pattern 22B. The inductor pattern 22A and the inductor pattern 22B have the same shape. The inductor pattern 22A and the inductor pattern 22B are disposed to face each other in the second direction D2.

The seventh conductor 16, the eighth conductor 17, and the fourth inductor conductor 22 constitute a fourth inductor L4 (see FIG. 7). The axial direction of the fourth inductor L4 including the seventh conductor 16, the eighth conductor 17, and the fourth inductor conductor 22 is along the first direction D1.

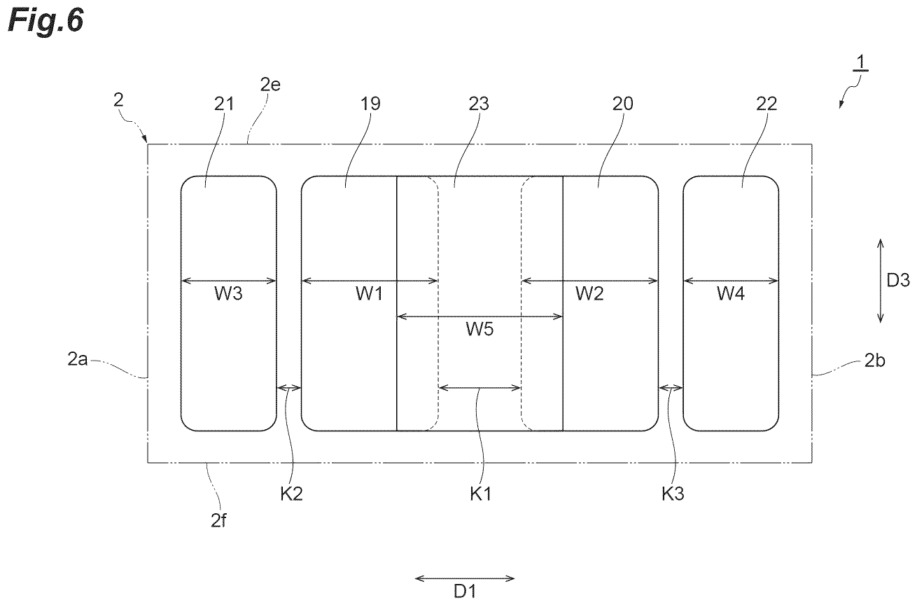

As illustrated in FIG. 6, in the present embodiment, a width W1 of the first inductor conductor 19 is equal to a width W2 of the second inductor conductor 20. A width W3 of the third inductor conductor 21 is equal to a width W4 of the fourth inductor conductor 22. In the present embodiment, the width W1 of the first inductor conductor 19 and the width W2 of the second inductor conductor 20 are greater than the width W3 of the third inductor conductor 21 and the width W4 of the fourth inductor conductor 22 (W1 and W2>W3 and W4). The first inductor conductor 19, the second inductor conductor 20, the third inductor conductor 21, and the fourth inductor conductor 22 are equal in length in the third direction D3.

The first inductor conductor 19 (first inductor L1 (see FIG. 7)) and the second inductor conductor 20 (second inductor L2 (see FIG. 7)) are disposed adjacent to each other in the first direction D1. The first inductor conductor 19 and the third inductor conductor 21 (third inductor L3 (see FIG. 7)) are disposed adjacent to each other in the first direction D1. The second inductor conductor 20 and the fourth inductor conductor 22 (fourth inductor L4 (see FIG. 7)) are disposed adjacent to each other in the first direction D1. A distance K1 between the first inductor conductor 19 and the second inductor conductor 20 is greater than a distance K2 between the first inductor conductor 19 and the third inductor conductor 21 and a distance K3 between the second inductor conductor 20 and the fourth inductor conductor 22 (K1>K2 and K3). The distance K2 between the first inductor conductor 19 and the third inductor conductor 21 is equal to the distance K3 between the second inductor conductor 20 and the fourth inductor conductor 22 (K2=K3).

The shield conductor 23 is substantially rectangular. The shield conductor 23 is disposed at a position closer to the main surface 2c (position nearer the main surface 2c) than the first inductor conductor 19, the second inductor conductor 20, the third inductor conductor 21, or the fourth inductor conductor 22 is. That is, a distance between the shield conductor 23 and the main surface 2c is shorter than a distance between the main surface 2c and each of the first inductor conductor 19, the second inductor conductor 20, the third inductor conductor 21, and the fourth inductor conductor 22.

In the present embodiment, a width W5 of the shield conductor 23 is greater than the width W1 of the first inductor conductor 19 and the width W2 of the second inductor conductor 20 (W5>W1 and W2). That is, the width W5 of the shield conductor 23 is greater than the width W3 of the third inductor conductor 21 and the width W4 of the fourth inductor conductor 22 (W5>W3 and W4). The shield conductor 23 is equal in length to each of the first inductor conductor 19, the second inductor conductor 20, the third inductor conductor 21, and the fourth inductor conductor 22 in the third direction D3. An area of the shield conductor 23 (the area as viewed from the second direction D2) is ½ or less of an area of the main surface 2c.

As illustrated in FIG. 6, the shield conductor 23 is positioned between the first inductor conductor 19 and the second inductor conductor 20 as viewed from the second direction D2. In the present embodiment, the shield conductor 23 is positioned between the first inductor conductor 19 and the second inductor conductor 20 as viewed from the second direction D2, and overlaps the first inductor conductor 19 and the second inductor conductor 20. The shield conductor 23 overlaps a part of each of the first inductor conductor 19 and the second inductor conductor 20. That is, the shield conductor 23 has a portion positioned between the first inductor conductor 19 and the second inductor conductor 20, and a portion overlapping the first inductor conductor 19 and the second inductor conductor 20, as viewed from the second direction D2.

An area where the shield conductor 23 and the first inductor conductor 19 overlap each other is smaller than an area where the shield conductor 23 and the first inductor conductor 19 do not overlap each other (area where the first inductor conductor 19 is exposed as viewed from the second direction D2). An area where the shield conductor 23 and the second inductor conductor 20 overlap each other is smaller than an area where the shield conductor 23 and the second inductor conductor 20 do not overlap each other (area where the second inductor conductor 20 is exposed as viewed from the second direction D2). The shield conductor 23 does not overlap the third inductor conductor 21 and the fourth inductor conductor 22 as viewed from the second direction D2. That is, the shield conductor 23 does not overlap all the inductors disposed in the element body 2 as viewed from the second direction D2.

As illustrated in FIG. 5, the connection conductor 24 connects the first conductor 10, the third conductor 12, and the ninth conductor 18. The connection conductor 24 extends in the first direction D1. The connection conductor 24 is connected to an end portion on the other side of the first conductor 10 and an end portion on the other side of the third conductor 12. The connection conductor 24 connects the end portion on the other side of the first conductor 10 and the end portion on the other side of the third conductor 12 at the same height position in the second direction D2. The connection conductor 24 is connected to the end portion on the other side of the ninth conductor 18 in the second direction D2 (a midway portion in the extending direction of the ninth conductor 18). As a result, the first conductor 10 and the third conductor 12 are shorter in length in the second direction D2 than the ninth conductor 18.

The capacitor conductor 25 faces a part of each of the capacitor conductor 26 and the capacitor conductor 27. The capacitor conductor 26 is connected to an end portion on the other side of the fifth conductor 14 (main surface 2d side). The capacitor conductor 27 is connected to an end portion on the other side of the seventh conductor 16.

The capacitor conductor 28 is connected to an end portion on the other side of the second conductor 11. The capacitor conductor 29 is connected to an end portion on the other side of the fourth conductor 13. The capacitor conductor 30 is connected to an end portion on the other side of the fifth conductor 14. The capacitor conductor 31 is connected to an end portion on the other side of the seventh conductor 16. The capacitor conductor 32 faces a part of each of the capacitor conductor 28 and the capacitor conductor 29 and a part of each of the capacitor conductor 36 and the capacitor conductor 37. The capacitor conductor 33 is connected to an end portion on the other side of the ninth conductor 18.

The capacitor conductor 34 is connected to an end portion on the other side of the sixth conductor 15. The capacitor conductor 34 is electrically connected to the second terminal electrode 4 via via conductors. The capacitor conductor 35 is connected to an end portion on the other side of the eighth conductor 17. The capacitor conductor 35 is electrically connected to the third terminal electrode 5 via via conductors. The capacitor conductor 36 is connected to an end portion on the other side of the second conductor 11. The capacitor conductor 37 is connected to an end portion on the other side of the fourth conductor 13. The capacitor conductor 38 is connected to an end portion on the other side of the ninth conductor 18. The capacitor conductor 38 faces a part of each of the capacitor conductor 30 and the capacitor conductor 31.

FIG. 7 is an equivalent circuit diagram of the electronic component 1 illustrated in FIG. 1. As illustrated in FIG. 7, the electronic component 1 includes a first port PI, a second port P2, a ground Gnd, the first inductor L1, the second inductor L2, the third inductor L3, the fourth inductor L4, a fifth inductor L5, a first capacitor C1, a second capacitor C2, a third capacitor C3, a fourth capacitor C4, a fifth capacitor C5, a sixth capacitor C6, a seventh capacitor C7, an eighth capacitor C8, a ninth capacitor C9, a tenth capacitor C10, an eleventh capacitor C11, and a twelfth capacitor C12.

The first port PI includes the second terminal electrode 4. The second terminal electrode 4 is an input/output terminal. The second port P2 includes the third terminal electrode 5. The third terminal electrode 5 is an input/output terminal. The ground Gnd includes the first terminal electrode 3. The first terminal electrode 3 is a ground terminal.

The first inductor L1 includes the first conductor 10, the second conductor 11, and the first inductor conductor 19. The second inductor L2 includes the third conductor 12, the fourth conductor 13, and the second inductor conductor 20. The third inductor L3 includes the fifth conductor 14, the sixth conductor 15, and the third inductor conductor 21. The fourth inductor L4 includes the seventh conductor 16, the eighth conductor 17, and the fourth inductor conductor 22. The fifth inductor L5 includes the ninth conductor 18.

The first capacitor C1 includes the capacitor conductor 33 and the capacitor conductor 36. The second capacitor C2 includes the capacitor conductor 33 and the capacitor conductor 37. The third capacitor C3 includes the capacitor conductor 30 and the capacitor conductor 34. The fourth capacitor C4 includes the capacitor conductor 31 and the capacitor conductor 35.

The fifth capacitor C5 includes the capacitor conductor 30 and the capacitor conductor 38. The sixth capacitor C6 includes the capacitor conductor 31 and the capacitor conductor 38. The seventh capacitor C7 includes the capacitor conductor 25 and the capacitor conductor 26. The eighth capacitor C8 includes the capacitor conductor 25 and the capacitor conductor 27.

The ninth capacitor C9 includes the capacitor conductor 26 and the capacitor conductor 28. The tenth capacitor C10 includes the capacitor conductor 32 and the capacitor conductor 36. The eleventh capacitor C11 includes the capacitor conductor 27 and the capacitor conductor 29. The twelfth capacitor C12 includes the capacitor conductor 32 and the capacitor conductor 37.

As described above, in the electronic component 1 according to the present embodiment, the shield conductor 23 is positioned at least between the first inductor conductor 19 and the second inductor conductor 20 as viewed from the second direction D2. As a result, in the electronic component 1, leakage of magnetic flux or the like from between the first inductor conductor 19 (first inductor L1) and the second inductor conductor 20 (second inductor L2) to the outside of the electronic component 1 can be suppressed by the shield conductor 23. Therefore, in the electronic component 1, it is possible to suppress deterioration of characteristics due to the leakage of magnetic flux or the like to the outside. In the electronic component 1, the shield conductor 23 also has a portion that does not overlap the first inductor conductor 19 or the second inductor conductor 20 as viewed from the second direction D2. As described above, in the electronic component, the shield conductor 23 does not entirely overlap the first inductor L1 and the second inductor L2 disposed in the element body 2. Therefore, in the electronic component 1, the capacitance formed between the shield conductor 23 and the first inductor L1 or second inductor L2 can be reduced. Therefore, in the electronic component 1, it is possible to suppress deterioration of the characteristics due to capacitance formation.

In the electronic component 1 according to the present embodiment, the shield conductor 23 does not overlap the third inductor conductor 21 (third inductor L3) and the fourth inductor conductor 22 (fourth inductor L4) as viewed from the second direction D2. As described above, in the electronic component 1, the shield conductor 23 does not overlap at least the third inductor L3 and the fourth inductor L4 among the first inductor L1, the second inductor L2, the third inductor L3, and the fourth inductor L4 disposed in the element body 2. That is, in the electronic component 1, the shield conductor 23 overlaps with some, but not all, of the inductors. Therefore, in the electronic component 1, no capacitance is formed between the shield conductor 23 and the third inductor L3 and fourth inductor L4. Therefore, in the electronic component 1, it is possible to suppress deterioration of the characteristics due to capacitance formation.

In the electronic component 1 according to the present embodiment, the shield conductor 23 has a portion positioned between the first inductor conductor 19 and the second inductor conductor 20, and a portion overlapping the first inductor conductor 19 and the second inductor conductor 20, as viewed from the second direction D2. With this configuration, since the shield conductor 23 has portions overlapping the first inductor conductor 19 and the second inductor conductor 20, leakage of magnetic flux or the like from between the first inductor conductor 19 and the second connection conductor 20 to the outside of the electronic component 1 can be further suppressed by the shield conductor 23.

In the electronic component 1 according to the present embodiment, the connection conductor 24 connects the end portion on the other side of the first conductor 10 and the end portion on the other side of the third conductor at the same height position in the second direction D2. The lengths of the first conductor 10 and the third conductor 12 in the second direction D2 are shorter than the length of the ninth conductor 18 in the second direction D2. With this configuration, coupling between the first inductor L1 and the second inductor L2 can be adjusted by changing the height position of the connection conductor 24 in the second direction D2, that is, by changing the lengths of the first conductor 10 and the third conductor 12. The inductance of the fifth inductor L5 can be secured by securing the length of the ninth conductor 18.

Hereinabove, embodiments of the present invention are described; however, the present invention is not necessarily limited to the above-described embodiments, and various changes can be made without departing from the gist thereof.

In the embodiment described above, the configuration including the first inductor L1, the second inductor L2, the third inductor L3, and the fourth inductor L4 has been described by way of example. However, the electronic component 1 may include at least two inductors of the first inductor L1 and the second inductor L2.

In the above-described embodiment, the configuration in which the shield conductor 23 has a portion overlapping each of the first inductor conductor 19 and the second inductor conductor 20 has been described by way of example. However, the shield conductor 23 is only sufficient to be positioned at least between the first inductor conductor 19 and the second inductor conductor 20 as viewed from the second direction D2.

In the above-described embodiment, the configuration in which the end portion on the other side of the first conductor 10, the end portion on the other side of the third conductor 12, and the ninth conductor 18 are electrically connected by the connection conductor 24 has been described by way of example. However, the first conductor 10, the third conductor 12, and the ninth conductor 18 may not be connected by the connection conductor 24.

The configuration in which the end portion on the other side of the first conductor 10, the end portion on the other side of the third conductor 12, and the ninth conductor 18 are electrically connected by the connection conductor 24 has been described by way of example. However, at least one of the first conductor 10, the second conductor 11, the third conductor 12, or the fourth conductor 13 may be connected to the ninth conductor 18 by the connection conductor 24.

In the above-described embodiment, the configuration in which the end portion on the other side of the first conductor 10 and the end portion on the other side of the third conductor 12 are connected by the connection conductor 24 at the same height position in the second direction D2 has been described by way of example. However, the end portion on the other side of the first conductor 10 and the end portion on 10 the other side of the third conductor 12 may be connected at different height positions.

What is claimed is:

1. An electronic component comprising:
an element body having a pair of end surfaces facing each other in a first direction, a main surface, and a mounting surface, the main surface and the mounting surface facing each other in a second direction;
a ground terminal disposed on the mounting surface of the element body;
a shield conductor disposed at a position closer to the main surface of the element body;
a conductor configured to electrically connect the ground terminal and the shield conductor; and
a first inductor and a second inductor disposed in the element body, each of the first inductor and the second inductor having an axial direction along the first direction, wherein
the first inductor includes a first conductor and a second conductor extending in the second direction, and a first connection conductor configured to connect an end portion of the first conductor closer to the main surface and an end portion of the second conductor closer to the main surface,
the second inductor includes a third conductor and a fourth conductor extending in the second direction, and a second connection conductor configured to connect an end portion of the third conductor closer to the main surface and an end portion of the fourth conductor closer to the main surface,
the first inductor and the second inductor are disposed adjacent to each other in the first direction,
the shield conductor is disposed at a position closer to the main surface in the second direction than the first connection conductor or the second connection conductor is, and
the shield conductor is at least positioned between the first connection conductor and the second connection conductor, and has a portion not overlapping the first connection conductor or the second connection conductor, as viewed from the second direction.

2. The electronic component according to claim 1, wherein
the shield conductor has a portion positioned between the first connection conductor and the second connection conductor and a portion overlapping the first connection conductor or the second connection conductor, as viewed from the second direction.

3. The electronic component according to claim 1, further comprising a third inductor disposed in the element body, with an axial direction of the third inductor along the first direction, wherein
the third inductor includes a fifth conductor and a sixth conductor extending in the second direction, and a third connection conductor configured to connect an end portion of the fifth conductor closer to the main surface and an end portion of the sixth conductor closer to the main surface, and
the shield conductor does not overlap the third connection conductor as viewed from the second direction.

4. The electronic component according to claim 1, wherein
an area of the shield conductor is ½ or less of an area of the main surface.

5. The electronic component according to claim 1, wherein
a width of the shield conductor is greater than a width of each of the first connection conductor and the second connection conductor.

6. The electronic component according to claim 1, wherein
the conductor is disposed between the first connection conductor and the second connection conductor as viewed from the second direction.

7. The electronic component according to claim 1, wherein
the conductor and an end portion, disposed closer to the mounting surface, of at least one of the first conductor, the second conductor, the third conductor, or the fourth conductor are electrically connected via a connection conductor.

8. The electronic component according to claim 7, wherein
the connection conductor connects two of end portions, disposed closer to the mounting surface, of the first conductor, the second conductor, the third conductor, and the fourth conductor at the same height position in the second direction, and
lengths in the second direction of two conductors connected to the connection conductor, among the first conductor, the second conductor, the third conductor, and the fourth conductor, are shorter than lengths in the second direction of two conductors not connected to the connection conductor.

9. An electronic component comprising:
an element body having a pair of end surfaces facing each other in a first direction, a main surface, and a mounting surface, the main surface and the mounting surface facing each other in a second direction;
a ground terminal disposed on the mounting surface of the element body;
a shield conductor disposed at a position closer to the main surface of the element body;
a conductor configured to electrically connect the ground terminal and the shield conductor; and
a first inductor, a second inductor, and a third inductor disposed in the element body, each of the first inductor, the second inductor, and the third inductor having an axial direction along the first direction, wherein
the first inductor includes a first conductor and a second conductor extending in the second direction, and a first connection conductor configured to connect an end portion of the first conductor closer to the main surface and an end portion of the second conductor closer to the main surface,
the second inductor includes a third conductor and a fourth conductor extending in the second direction, and a second connection conductor configured to connect an end portion of the third conductor closer to the main surface and an end portion of the fourth conductor closer to the main surface,
the third inductor includes a fifth conductor and a sixth conductor extending in the second direction, and a third connection conductor configured to connect an end portion of the fifth conductor closer to the main surface and an end portion of the sixth conductor closer to the main surface,
the first inductor and the second inductor are disposed adjacent to each other in the first direction,
the shield conductor is disposed at a position closer to the main surface in the second direction than the first connection conductor, the second connection conductor, or the third connection conductor is, and
the shield conductor is at least positioned between the first connection conductor and the second connection conductor, and does not overlap the third connection conductor, as viewed from the second direction.
